(19) United States
(12) Patent Application Publication
(10) Pub. No.: US 2021/0088903 A1
(43) Pub. Date: Mar. 25, 2021

(54) PHOTOSENSITIVE POLYIMIDE RESIN COMPOSITION AND POLYIMIDE FILM THEREOF

(71) Applicant: MICROCOSM TECHNOLOGY CO., LTD., Tainan City (TW)

(72) Inventors: Tang Chieh Huang, Tainan City (TW); Chau Chin Chuang, Tainan City (TW); Yu Chiao Shih, Tainan City (TW); Kun Han Hsieh, Tainan City (TW)

(73) Assignee: MICROCOSM TECHNOLOGY CO., LTD., Tainan City (TW)

(21) Appl. No.: 16/970,534

(22) PCT Filed: Jan. 23, 2019
(86) PCT No.: PCT/CN2019/072780

§ 371 Date: Aug. 17, 2020

(51) Int. Cl. G03F 7/037; C08J 5/18; C08G 73/10

(52) U.S. Cl. CPC G03F 7/037; C08J 2379/08; C08G 73/1071; C08J 5/18

(57) ABSTRACT

The present invention provides a photosensitive polyimide resin composition, which comprises (a) a photosensitive polyimide represented by formula (1); (b) titanium dioxide having a particle size of 0.2 μm to 10 μm; (c) a photo radical initiator; (d) a radical polymerizable compound; and (e) a solvent for dissolving the photosensitive polyimide;

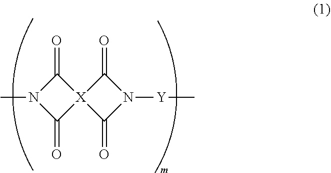

wherein X is derived from a tetracarboxylic dianhydride, Y is derived from a diamine, and m is a positive integer from 1 to 5000.

### BACKGROUND OF THE INVENTION

### Field of the Invention

The present invention relates to a photosensitive resin composition and, in particular, to a photosensitive resin composition comprising a photosensitive polyimide as the main component.

### Description of the Prior Art

Generally, polyimide resin is prepared by the condensation polymerization of aromatic tetracarboxylic acid or its derivatives, aromatic diamine, and aromatic diisocyanate. The prepared polyimide resin has excellent heat resistance, chemical resistance, and mechanical and electrical properties so it is widely used in electronic materials such as semiconductor encapsulants.

In the manufacturing process of semiconductor device that utilize polyimide, it is often necessary to use Micro Lithography to make circuit patterns. If a conventional polyimide is used, an additional photoresist must be used to perform etching. Therefore, the photosensitive polyimide (PSPI) can simplify the process because it has both the characteristics of photoresist and the insulating protective material, which makes considerable progress of the soft board electronic material process and makes PSPI a very popular and advanced material.

However, for certain design requirements, it is needed to have the insulating film with good shielding properties. In order to obtain a polyimide film with good shielding properties, one of the conventional methods is to coat a white resin (for example, an epoxy resin or an acrylic resin) on a polyimide film to form a dual-layered composite polyimide film. However, although this method can make the polyimide film white and has a shielding property, the additionally coated resin generally increases the manufacturing cost and decreases the yield. Therefore, there exists a need for a more cost-effective polyimide film.

### SUMMARY OF THE INVENTION

In view of the above, it is an object of the present invention to provide a more cost-effective polyimide film.

To achieve the above objective, the present invention provides a photosensitive polyimide resin composition, which comprises (a) a photosensitive polyimide represented by formula (1); (b) titanium dioxide having a particle size of 0.2 μm to 10 μm; (c) a photo radical initiator; (d) a radical polymerizable compound; and (e) a solvent for dissolving the photosensitive polyimide;

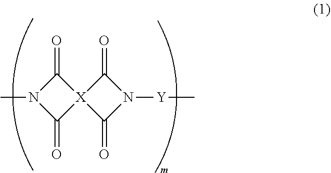

wherein X is derived from a tetracarboxylic dianhydride, Y is derived from a diamine, and m is a positive integer from 1 to 5000.

Preferably, the tetracarboxylic dianhydride is 3,3′,4,4′-biphenyltetracarboxylic dianhydride, 3,3′,4,4′-benzophenone tetracarboxylic dianhydride, 4,4′-oxydiphthalic anhydride, bis(3,4-dicarboxyphenyl)methane dianhydride, 2,2-di(3,4-dicarboxyphenyl)propane dianhydride, 2,2-bis(3,4-dicarboxyphenyl)propane dianhydride, 1,3-bis(3,4-dicarboxyphenoxy)benzene dianhydride, 1,4-bis(3,4-dicarboxyphenoxy)benzene dianhydride, 4,4′-bis(3,4-dicarboxyphenoxy)biphenyl dianhydride, 2,2-bis[4-(3,4-dicarboxyphenoxy)phenyl]propane dianhydride, ethylene glycol bis(trimellitic anhydride) (TMEG), propylene glycol bis(trimellitic anhydride) (TMPG), 1,2-propanediol bis(trimellitic anhydride), butanediol bis(trimellitic anhydride), 2-methyl-1,3-propanediol bis(trimellitic anhydride), dipropylene glycol bis(trimellitic anhydride), 2-methyl-2,4-pentanediol bis(trimellitic anhydride), diethylene glycol bis(trimellitic anhydride), tetraethylene glycol bis(trimellitic anhydride), hexaethylene glycol bis(trimellitic anhydride), neopentyl glycol bis(trimellitic anhydride), hydroquinone bis(2-hydroxyethyl)ether bis(trimellitic anhydride), 2-phenyl-5-(2,4-xylyl)-1,4-hydroquinone bis(trimellitic anhydride), 2, 3-dicyanohydroquinone cyclobutane-1,2,3,4-tetracarboxylic dianhydride, 1,2,3,4-cyclopentanetetracarboxylic dianhydride, 1,2,4,5-cyclohexane tetracarboxylic dianhydride, bicyclo[2.2.1]heptane-2,3,5,6-tetracarboxylic dianhydride, bicyclo[2.2.2]oct-7-ene-2,3,5,6-tetracarboxylic dianhydride, bicyclo[2.2.2]octane-2,3,5,6-tetracarboxylic dianhydride, 2,3,5-tricarboxy-cyclopentyl acetic dianhydride, bicyclo[2.2.1]heptane-2,3,5-tricarboxy-6-acetic dianhydride, decahydro-1,4,5,8-dimethanolnaphthalene-2,3,6,7-tetracarboxylic dianhydride, butane-1,2,3,4-tetracarboxylic dianhydride, 3,3′,4,4′-dicyclohexyltetracarboxylic dianhydride, or a combination of two or more thereof.

Preferably, the diamine is 3,3′-diaminodiphenyl sulfone, 4,4′-diaminodiphenyl sulfone, 3,3′-methylenediphenylamine, 4,4′-methylenediphenylamine, 2,2-bis(4-aminophenyl)propane, 2,2-bis(4-aminophenyl)hexafluoropropane, 2,2′-bis(trifluoromethyl)benzidine, 2,2′-dimethylbenzidine, 3,3′-dihydroxybenzidine, 1,3-bis(3-aminophenoxy)benzene, 1,3-bis(4-aminophenoxy)benzene, 1,4-bis(4-aminophenoxy)benzene, 4,4′-bis(4-aminophenoxy)biphenyl, 2,2-bis[4-(4-aminophenoxy)phenyl]propane, 2,2-bis[4-(4-aminophenoxy)phenyl]-1,1,1,3,3,3-hexafluoropropane, 1,3-bis[4-(3-aminophenoxy)benzoyl]benzene, 4,4′-diaminobenzanilide, 2,2-bis(3-amino-4-hydroxyphenyl)hexafluoropropane, 5-amino-2-(p-aminophenyl)benzoxazole, 6-amino-2-(p-aminophenyl)benzoxazole, or a combination of two or more thereof.

Preferably, the titanium dioxide has a particle diameter of 0.3 μm to 5 μm.

Preferably, the titanium oxide accounts for 30% to 70% by weight of a solid content of the photosensitive polyimide resin composition. More preferably, the titanium oxide accounts for 35% to 50% by weight of a solid content of the photosensitive polyimide resin composition.

Preferably, the radical polymerizable compound is a compound having at least two (meth)acrylate groups.

Preferably, the radical polymerizable compound is a polyamic acid ester having the (meth)acrylate group. More preferably, a content of the polyamic acid ester having the (meth)acrylate group in the radical polymerizable compound is from 10% to 98% by weight.

Preferably, a polyimide film formed from the resin composition has a reflectance of 85% or more at a wavelength of 450 nm.

Preferably, a color difference ΔE*ab of a polyimide film formed from the resin composition before and after 260° C. reflow is 2 or less.

Preferably, a color difference ΔE*ab of a polyimide film formed from the resin composition before and after 200° C. baking for 2 hours is 2 or less.

Preferably, a hardness of a polyimide film formed from the resin composition is 7H or more.

Preferably, a polyimide film formed from the resin composition has a pore pattern having a pore diameter of 100 μm or less.

The present invention also provides a polyimide film formed from the aforementioned resin composition.

Preferably, a color difference ΔE*ab of the polyimide film before and after 260° C. reflow is 2 or less.

Preferably, a color difference ΔE*ab of the polyimide film before and after 200° C. baking for 2 hours is 2 or less.

Preferably, a hardness of the polyimide film is 7H or more.

Preferably, the polyimide film has a pore pattern having a pore diameter of 100 μm or less.

The present invention further provides a substrate, which comprises the polyimide film described above.

The photosensitive polyimide resin composition of the present invention is formed by a combination of specific components, and therefore the resultant polyimide film has the characteristics of low yellowness and high reflectivity by adding titanium oxide having a particle diameter of 0.2 μm to 10 μm.

### DETAILED DESCRIPTION OF THE EMBODIMENTS

The present invention provides a photosensitive polyimide resin composition, which comprises (a) a photosensitive polyimide represented by formula (1); (b) titanium dioxide having a particle size of 0.2 μm to 10 μm; (c) a photo radical initiator; (d) a radical polymerizable compound; and (e) a solvent for dissolving the photosensitive polyimide;

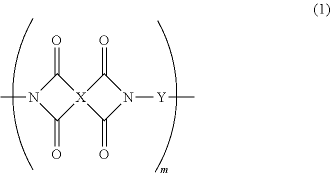

wherein X is derived from a tetracarboxylic dianhydride, Y is derived from a diamine, and m is a positive integer from 1 to 5000, such as 500, 1000, 1500, 2000, 2500, 3000, 3500, 4000, or 4500. In some embodiment, m is between any two of the foregoing values.

The photosensitive polyimide of the present invention is a solvent-soluble polyimide, which is prepared by the chemical cyclodehydration or thermal cyclodehydration of a diamine and a tetracarboxylic dianhydride. More specifically, the diamine and the tetracarboxylic dianhydride are usually dissolved in an organic solvent, and the resulting solution is stirred under controlled temperature conditions until the polymerization of tetracarboxylic dianhydride and diamine is completed, obtaining a polyimide precursor (i.e. polyamic acid). The concentration of the obtained polyamic acid solution is usually from 5% to 35% by weight, preferably from 10% to 30% by weight. When the concentration is within the range mentioned above, an appropriate molecular weight and solution viscosity can be obtained. In the present invention, the polymerization method of the polyimide is not particularly limited, and the order of addition of tetracarboxylic dianhydride and diamine monomers, the combination of the monomers, and the adding amount thereof are not particularly limited. For example, the polyimide of the present invention can undergo random or sequential polymerization of block components by conventional polymerization methods.

The method for preparing the polyimide by cyclodehydration of the polyimide precursor (polyamic acid) is not particularly limited. More specifically, it can use the chemically cyclodehydration method, which adds pyridine, triethylamine, or N,N-diisopropylethylamine, etc. that are optionally acting as an alkaline reagent and acetic anhydride serving as a dehydration agent into the polyamic acid under nitrogen or oxygen atmosphere. After the reaction is completed, the resultant colloid is washed by water and filtered to obtain the polyimide powder. Alternatively, the thermal cyclodehydration method may be used, which adds an azeotropic reagent (such as toluene or xylene) into the polyamic acid, raises the temperature up to 180 degrees Celsius, and then removes the water produced from the cyclodehydration of the polyamic acid and the azeotropic reagent. After the reaction is completed, the solvent-soluble polyimide can be obtained. In the preparation of the solvent-soluble polyimide, other reagents which enhance the reaction efficiency may be added, such as, but not limited to, a catalyst, an inhibitor, an azeotropic agent, a leveling agent, or a combination thereof.

The photosensitive polyimide of the present invention is obtained by polymerizing a tetracarboxylic dianhydride with a diamine. That is, in the present invention, X is a tetravalent organic group derived from the tetracarboxylic dianhydride, and Y is a divalent organic group derived from the diamine.

Examples of the tetracarboxylic dianhydride include, but are not limited to, 3,3′,4,4′-biphenyltetracarboxylic dianhydride, 3,3′,4,4′-benzophenone tetracarboxylic dianhydride, 4,4′-oxydiphthalic anhydride, bis(3,4-dicarboxyphenyl)methane dianhydride, 2,2-bis(3,4-dicarboxyphenyl)propane dianhydride, 2,2-bis(3,4-dicarboxyphenyl)propane dianhydride, 1,3-bis(3,4-dicarboxyphenoxy)phthalic anhydride, 1,4-bis(3,4-dicarboxyphenoxy)phthalic anhydride, 4,4′-bis(3,4-dicarboxyphenoxy)biphenyl dianhydride, 2,2-bis[4-(3,4-dicarboxyphenoxy)phenyl]propane dianhydride, ethylene glycol bis(trimellitic anhydride) (TMEG), propylene glycol bis(trimellitic anhydride) (TMPG), 1,2-propanediol bis(trimellitic anhydride), butanediol bis(trimellitic anhydride), 2-methyl-1,3-propanediol bis(trimellitic anhydride), dipropylene glycol bis(trimellitic anhydride), 2-methyl-2,4-pentanediol bis(trimellitic anhydride), diethylene glycol bis(trimellitic anhydride), tetraethylene glycol bis(trimellitic anhydride), hexaethylene glycol bis(trimellitic anhydride), neopentyl glycol bis(trimellitic anhydride), hydroquinone bis(2-hydroxyethyl)ether bis(trimellitic anhydride), 2-phenyl-5-(2,4-xylyl)-1,4-hydroquinone bis(trimellitic anhydride), 2, 3-dicyanohydroquinone cyclobutane-1,2,3,4-tetracarboxylic dianhydride, 1,2,3,4-cyclopentanetetracarboxylic dianhydride, 1,2,4,5-cyclohexane tetracarboxylic dianhydride, bicyclo[2.2.1]heptane-2,3,5,6-tetracarboxylic dianhydride, bicyclo[2.2.2]oct-7-ene-2,3,5,6-tetracarboxylic dianhydride, bicyclo[2.2.2]octane-2,3,5,6-tetracarboxylic dianhydride, 2,3,5-tricarboxy-cyclopentyl acetic dianhydride, bicyclo[2.2.1]heptane-2,3,5-tricarboxy-6-acetic dianhydride, decahydro-1,4,5,8-dimethanolnaphthalene-2,3,6,7-tetracarboxylic dianhydride, butane-1,2,3,4-tetracarboxylic dianhydride, and 3,3′,4,4′-dicyclohexyltetracarboxylic dianhydride. These tetracarboxylic dianhydrides may be used singly or in combination of two or more (such as three, four, five) thereof.

Examples of the diamine include, but are not limited to, 3,3′-diaminodiphenyl sulfone, 4,4′-diaminodiphenyl sulfone, 3,3′-methylenediphenylamine, 4,4′-methylenediphenylamine, 2,2-bis(4-aminophenyl)propane, 2,2-bis(4-aminophenyl)hexafluoropropane, 2,2′-bis(trifluoromethyl)benzidine, 2,2′-dimethylbenzidine, 3,3′-dihydroxybenzidine, 1,3-bis(3-aminophenoxy)benzene, 1,3-bis(4-aminophenoxy)benzene, 1,4-bis(4-aminophenoxy)benzene, 4,4′-bis(4-aminophenoxy)biphenyl, 2,2-bis[4-(4-aminophenoxy)phenyl]propane, 2,2-bis[4-(4-aminophenoxy)phenyl]-1,1,1,3,3,3-hexafluoropropane, 1,3-bis[4-(3-aminophenoxy)benzoyl]benzene, 4,4′-diaminobenzanilide, 2,2-bis(3-amino-4-hydroxyphenyl)hexafluoropropane, 5-amino-2-(p-aminophenyl)benzoxazole, 6-amino-2-(p-aminophenyl)benzoxazole, and the like. These diamines may be used singly or in combination of two or more (such as three, four, five) thereof.

In the present invention, in consideration of other characteristics, such as pattern formability, the titanium oxide preferably accounts for 30% to 70%, more preferably 35% to 50% by weight of the solid content of the photosensitive polyimide resin composition.

The photo radical initiator is an initiator commonly used in photosensitive resin composition. Examples of the photo radical initiator may include, but are not limited to, an oxime compound such as oxime derivatives, a ketone compound (including acetophenones, benzophenones, and thioxanthone compounds), a triazine compound, a benzoin compound, a metallocene compound, a triazine compound, or an acylphosphine compound. These initiators may be used singly or in combination of two or more (such as three, four, five) thereof. From the viewpoint of exposure sensitivity, the photo radical initiator is preferably an acylphosphine compound or an oxime compound.

Examples of the oxime compound such as oxime derivatives may include, but are not limited to, o-acyloxime compounds, 2-(O-benzoyloxime)-1-[4-(phenylthio)phenyl]-1,2-octanedione, 1-(O-acetyloxime)-1-[9-ethyl-6-(2-methylbenzoyl)-9H-carbazol-3-yl] ethyl ketone, O-ethoxycarbonyl-α-oxyamino-1-phenylpropan-1-one, and the like. These compounds may be used singly or in combination of two or more (such as three, four, five) thereof. Examples of the O-acyloxime compound may include, but are not limited to, 1,2-octanedione, 2-dimethylamino-2-(4-methylbenzyl)-1-(4-morpholine-4-yl-phenyl)-butan-1-one, 1-(4-phenylsulfanylphenyl)-butane-1,2-dione-2-oxime-O-benzoate, 1-(4-phenylsulfanylphenyl)-octane-1,2-dione-2-oxime-O-benzoate, 1-(4-phenylsulfanylphenyl)-octan-1-oxime-O-acetate, 1-(4-phenylsulfanylphenyl)-butan-1-oxime-O-acetate, and the like. Those O-acyloxime compounds may be used singly or in combination of two or more (such as three, four, five) thereof. Examples of the acylphosphine compound comprise bis(2,4,6-trimethylbenzoyl)phenylphosphine oxide or 2,4,6-trimethylbenzoyl-diphenyloxophosphine, but are not limited thereto. Those acylphosphine compounds may be used singly or in combination of two or more thereof.

The content of the photo radical initiator is preferably 0.1% to 30% by weight, more preferably 1% to 20% by weight, based on that of the main resin. When the content of the photo radical initiator is within the range mentioned above, the polyimide film can be ensured to have excellent reliability, better resolution of the pattern, and heat resistance, light resistance and chemical resistance due to the compact contact because the polyimide is sufficiently cured while exposure to light during pattern formation.

The photo radical initiator can be used with a photosensitizer that is able to cause a chemical reaction by absorbing light and being excited, and then transfer its energy. Examples of the photosensitizer may include, but are not limited to, tetraethylene glycol bis-3-m ercaptopropionate, pentaerythritol tetrakis-mercaptopropionate, dipentaerythritol tetraalkyl-3-mercaptopropionate, and the like. These photosensitizers may be used singly or in combination of two or more (such as three) thereof.

The radical polymerizable compound is a photo radical crosslinking agent, and does not have particularly limited types. In a preferred embodiment of the present invention, the radical polymerizable compound is a compound having at least two (meth)acrylate groups, such as the compound having two (meth)acrylate groups, the compound having three (meth)acrylate groups, the compound having four (meth)acrylate groups, the compound having five (meth)acrylate groups, or the compound having six (meth)acrylate groups. Examples of the compound having at least two (meth)acrylate groups may include, but are not limited to, ethylene glycol dimethacrylate; EO modified diacrylate of bisphenol A (n=2 to 50) (EO being Ethylene oxide, and n being the molar number of ethylene oxide added); EO modified diacrylate of bisphenol F; BLEMMER PDE-100®, PDE-200®, PDE-400®, PDE-600®, PDP-400®, PDBE-200A®, PDBE-450A®, ADE-200®, ADE-300®, ADE-400A®, ADP-400® (NOF Co., Ltd.); Aronix M-210®, M-240® and/or M-6200® (manufactured by Toagosei Synthetic Chemical Co., Ltd.); KAYARAD HDDA®, HX-220®, R-604® and/or R-684® (Nippon Kayaku Co., Ltd.); V-260®, V-312® and/or V-335HP® (Osaka Organic Chemical Ind., Ltd.); Trimethylolpropane triacrylate (TMPTA); methylolpropane tetraacrylate; Glycerine propoxylate triacrylate; triethoxytrimethylolpropane triacrylate; trimethylolpropane trimethacrylate; tris(2-hydroxyethyl)isocyanate triacrylate (THEICTA); pentaerythritol troacrylate; pentaerythritol hexaacrylate; Aronix M-309®, M-400®, M-405®, M-450®, M-710®, M-8030® and/or M-8060® (Toagosei Synthetic Chemical Co., Ltd.); KAYARAD DPHA®, TMPTA®, DPCA-20®, DPCA-30®, DPCA-60® and/or DPCA-120® (Nippon Chemical Co., Ltd.); V-295®, V-300®, V-360®, V-GPT®, V-3PA® and/or V-400® (Osaka Yuki Kayaku Kogyo Co., Ltd).

In another preferred embodiment of the present invention, the radical polymerizable compound is a polyamic acid ester having a (meth)acrylate group, i.e. a polyamic acid ester having a (meth)acrylate group (CH₂═C(CH₃)—COO—) or a polyamic acid ester having an acrylate group (CH₂═CH—COO—). In a preferred embodiment, the polyamic acid ester having a (meth)acrylate group is obtained by reacting tetracarboxylic dianhydride, 2-hydroxyethyl methacrylate, and a diamine.

In the photosensitive polyimide resin composition, the content of the radical polymerizable compound is preferably 1% to 50% by mass, based on the total solid content of the photosensitive polyimide resin composition, from the viewpoint of good radical polymerizability and heat resistance. The lower limit is more preferably 5% by mass or more. The upper limit is more preferably 40% by mass or less. The radical polymerizable compound may be used singly or in combination of two or more (for example, two, three, or four) thereof. Preferably, three kinds of the radical polymerizable compound are mixed for use and, more preferably, at least one of the three kinds of the radical polymerizable compound is the polyamic acid ester having the (meth)acrylate group.

In the present invention, the content of the polyamic acid ester having the (meth)acrylate group in the radical polymerizable compound is preferably 10% to 98% by weight, more preferably 30% to 95% by weight, particularly preferably 50% to 90% by weight. When the content of the polyamic acid ester having the (meth)acrylate group is within the above range, a cured film having more excellent curability and heat resistance can be formed. The radical polymerizable compounds may be used singly or in combination of two or more thereof. When two or more are used, it is preferable that the total amount of the radical polymerizable compounds is within the above range.

When the content of the radical polymerizable compound is within the above range, the cross-linking bond produced by the radical reaction initiated by the photo radical initiator and the UV radiation can improve the pattern forming ability. In addition, curing by exposure can be sufficiently achieved during pattern formation, and the contrast of the alkaline developer can be improved.

In the present invention, the solvent is not particularly limited as long as it can dissolve the photosensitive polyimide. Examples of the solvent include, but are not limited to, ethyl acetate, n-butyl acetate, γ-butyrolactone, ε-caprolactone, diethylene glycol dimethyl ether, tetrahydrofuran, ethylene glycol monomethyl ether, ethylene glycol monoethyl ether, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, and propylene glycol monopropyl ether acetate, methyl ethyl ketone, cyclohexanone, cyclopentanone, N-methylpyrrolidone, dimethylformamide, dimethyl sulfoxide or N,N-dimethylacetamide (DMAc). These solvents may be used singly or in combination of two or more (such as two, three or four) thereof. From the viewpoint of improving the state of the coated surface, it is preferred to mix two or more solvents. From the viewpoint of coatability, when the photosensitive resin composition contains the solvent, the content of the solvent is preferably 5% to 80% by mass, more preferably 5% to 70% by mass, and particularly preferably 10% to 60% by mass, based on the total solid amount of the photosensitive resin composition. One or two or more kinds of solvent could be used. When two or more kinds of solvent are used, it is preferable that the total amount of the solvents is within the above range.

The photosensitive polyimide resin composition of the present invention may or may not be added with an additive. The selection of the additive may depend on the application of the photosensitive polyimide resin composition of the present invention. Examples of the additive include, but are not limited to, higher fatty acid derivatives, surfactants, inorganic particles, curing agent, curing catalysts, fillers, antioxidants, ultraviolet absorbers, anticoagulants, leveling agents or a combination thereof. When the additives are formulated, the total amount of the additives is preferably 10% by mass or less, based on the solid amount of the photosensitive resin composition.

The present invention also provides a polyimide film formed from the resin composition described above.

In a preferred embodiment, a color difference ΔE*ab of the polyimide film before and after 260° C. reflow is 2 or less.

In a preferred embodiment, a color difference ΔE*ab of the polyimide film before and after 200° C. baking for 2 hours is 2 or less.

In a preferred embodiment, a hardness of the polyimide film is 7H or more.

In a preferred embodiment, the polyimide film has a pore pattern having a pore diameter of 100 μm or less.

The interlayer insulating film and the protective film of the present invention can be prepared by coating (e.g. spin coating or cast coating) a substrate with the photosensitive polyimide resin composition, followed by prebaking to remove the solvent and then form a pre-baked film. The prebaking conditions vary depending on the kind and formulation ratio of the individual components, and are usually at a temperature of 80 to 120° C. for 5 to 15 minutes. After prebaking, the coating film is exposed through a mask, and the light used for exposure is preferably ultraviolet of g-line, h-line, i-line, etc., and the ultraviolet irradiation device may be (ultra) high-pressure mercury lamp and metal halogen lamp. Then, the exposed film is immersed in a developing solution at a temperature of 20 to 40° C. for 1 to 2 minutes to remove the unnecessary portions and form a specific pattern. Examples of the developer include, but are not limited to, methanol, ethanol, propanol, isopropanol, butanol, ethyl acetate, n-butyl acetate, γ-butyrolactone, ε-caprolactone, diethylene glycol dimethyl ether, tetrahydrofuran, ethylene glycol monomethyl ether, ethylene glycol monoethyl ether, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, propylene glycol monopropyl ether acetate, methyl ethyl ketone, cyclohexanone, cyclopentanone, N-methyl pyrrolidone, dimethylformamide, dimethyl sulfoxide or N,N-dimethylacetamide. The developer may also be a combination of two or more of the above organic solvents.

When a developer composed of the above organic solvents is used, an organic solvent is usually used for washing after development, followed by air-drying with compressed air or compressed nitrogen. Next, post-baking treatment is performed using a heating device such as a hot plate or an oven, and the temperature of the post-baking treatment is usually between 180 to 250° C. After the above processing steps, a protective film can be formed.

Accordingly, the present invention further provides a substrate comprising the aforementioned polyimide film.

To highlight the efficacy of the present invention, the inventors have completed the examples and comparative examples in the manners set forth below. The following examples and comparative examples are experimental data of the inventors and do not fall in the scope of the prior art. The following examples and comparative examples are intended to further illustrate the present invention, but not intended to limit the scope of the invention. Any changes and modifications made by those skilled in the art without departing from the spirit of the invention are within the scope of the invention.

### Synthesis Example 1: Preparation of Photosensitive Polyimide

62.12 g (0.194 mole) of 2,2′-bis(trifluoromethyl)benzidine (TFMB) and 500 g of DMAc were placed in a three-necked flask. After stirring at 30° C. till complete dissolution, 84.86 g (0.200 mole) of propylene glycol bis(trimellitic anhydride) (TMPG) was added, followed by continuous stirring and reaction at 25° C. for 24 hours to obtain a polyamic acid solution. Then, 23.00 g (0.290 mole) of pyridine and 59.4 g (0.582 mole) of acetic anhydride were further added, followed by continuous stirring and reaction at 25° C. for 24 hours. After the reaction is completed, polyimide was precipitated in 5 liters of water, and the mixture of water and polyimide was stirred at 5000 rpm for 15 minutes. The polyimide was obtained after filtration, and then poured again into 4 liters of water, stirred for 30 minutes, and subject to filtration again. Thereafter, the obtained polyimide was dried at 45° C. for 3 days under reduced pressure to obtain dried polyimide (TMPG-TFMB PI (A1)). The test results of A1 obtained by ¹H-NMR are shown below (the ratio of hydrogen number is defined by the non-repeating structure unit). ¹H-NMR (500 MHz, DMSO-d₆, δ ppm) 8.47-8.20 (4H, m), 8.15-7.70 (6H, m), 7.47-7.41 (2H, m), 4.45-4.38 (4H, m), 2.48-2.39 (2H, m); FT-IR (cm⁻¹) 3066, 2971, 1778, 1726, 1601, 1486, 1426, 1310, 1273, 1138, 1078, 840, 722.

### Synthesis Example 2: Preparation of Polyamic Acid Ester Having Methacrylate Group

[Synthesis of a polyamic acid ester having an acrylate group (D3), derived from propylene glycol bis(trimellitic anhydride) (TMPG), 2,2′-bis(trifluoromethyl)benzidine (TFMB), and 2-hydroxyethyl methacrylate (HEMA)]

In a four-necked flask, 16.97 g (40.0 mmol) of propylene glycol bis(trimellitic anhydride) (TMPG), 10.94 g (84.0 mmol) of 2-hydroxyethyl methacrylate (HEMA), 0.04 g (0.4 mmol) of hydroquinone, 3.16 g (84.0 mmol) of pyridine, and 80 mL of tetrahydrofuran were added sequentially and stirred at 50° C. for 3 hours, and a clear solution was obtained after a few minutes from the start of heating. The reaction mixture was cooled to room temperature, and then cooled to −10° C. While maintaining the temperature at −10° C.±4° C., 11.9 g (100.0 mmol) of thionyl chloride was added over 10 minutes. The viscosity increases during the addition of thionyl chloride. After dilution with 50 mL of dimethylacetamide, the reaction mixture was stirred at room temperature for 2 hours. The temperature was kept at −10° C.±4° C., and 11.62 g (200.0 mmol) of propylene oxide as a neutralizing agent was used to neutralize excess hydrochloric acid. A solution of 12.75 g (39.8 mmol) of 2,2′-bis(trifluoromethyl)benzidine (TFMB) dissolved in 100 mL of dimethylacetamide was added dropwise into the reaction mixture in 20 minutes, and the reaction mixture was stirred at room temperature for 15 hours. After the reaction is completed, the polyamic acid ester having the methacrylate group was precipitated with 5 liters of water, and the mixture of water and the polyamic acid ester having the methacrylate group was stirred at 5000 rpm for 15 minutes. The polyamic acid ester having the methacrylate group was obtained after filtration, and then poured again into 4 liters of water, stirred for 30 minutes, and subject to filtration again. Thereafter, the obtained polyamic acid ester having the methacrylate group was dried at 45° C. for 3 days under reduced pressure to obtain dried polyamic acid ester having the methacrylate group (HEMA-TMPG-TFMB PAE (D3)). The test results of D3 obtained by ¹H-NMR are shown below (the ratio of hydrogen number is defined by the non-repeating structure unit). ¹H-NMR (500 MHz, DMSO-d₆, δ ppm) 11.10-11.07 (2H, m, NH), 8.46-8.43 (2H, m), 8.39-8.32 (2H, m), 8.12-8.01 (2H, m), 7.60-7.38 (4H, m), 7.30-7.23 (2H, m), 4.49-4.30 (12H, m), 2.49-2.40 (2H, m), 1.84-1.80 (6H, m); FT-IR (cm⁻¹) 2923, 2821 (C—H), 1780 (C═O), 1725 (C═O), 1648 (CH₂═CH), 1615, 1485, 1425, 1366, 1273, 1241, 1198, 1134, 1078, 842, 742.

### Examples 1-6 and Comparative Examples 1-4: Preparation of Photosensitive Polyimide Resin Compositions

The components used in the photosensitive polyimide resin composition are as follows. The components listed below were mixed with a solvent in a weight ratio as shown in Table 1 to prepare a solution having a solid content of 30%, which is a coating solution of a photosensitive polyimide resin composition.

Component A1: TMPG-TFMB PI

Component B1: TiO₂ having a particle diameter of 0.4 μm

Component B2: TiO₂ having a particle diameter of 5.0 μm

Component B3: TiO₂ having a particle diameter of 10.0 μm

Component B4: TiO₂ having a particle diameter of 0.1 μm

Component B5: TiO₂ having a particle diameter of 12.0 μm

Component Cl: Irgacure 184

Component D1: Polydipentaerythritol hexaacrylate (DPHA)

Component D2: PDBE-450A (NOF)

Component D3: HEMA-TMPG-TFMB PAE

Component E1: DMAc

Evaluation Results

[Pattern Formability]

The photosensitive resin composition was coated on a copper foil substrate, and then dried at 90 degrees for 5 minutes to obtain a film. After exposure through a photomask, the exposed layer of the photosensitive polyimide resin composition was developed for 60 seconds by using cyclopentanone. Whether the line width of the formed pattern has good edge sharpness or not was evaluated by the following criteria. The smaller the line width of the photosensitive polyimide resin composition layer, the larger the difference in solubility of the light-irradiated portion and the non-light-irradiated portion with respect to the developer, resulting in preferable outcome. Further, the smaller the change in the line width with respect to the change in the exposure energy, the wider the exposure tolerance, which is a preferable result.

After observing the formed adhesive pattern by an optical microscope, the case where a thin line pattern having a line width/pitch width of 100 μm/100 μm or less was set to A, and the case where a thin line pattern having a line width/pitch width of more than 100 μm/100 μm was set to B to evaluate the pattern formability. The evaluation results are shown in Table 1.

<Reflectance>

The reflectance of the polyimide film formed from the photosensitive polyimide resin composition was measured at the wavelength of 550 nm using an integrating sphere spectrometer (X-RITE SP60).

<Yellowness>

The polyimide film formed from the photosensitive polyimide resin composition was measured for b value in the (L, a, b) color system using a spectrophotometer CM-600d (manufactured by Konica Minolta Sensing Co., Ltd.).

<Thermal Yellowing Resistance>

The sample was measured for ΔE value in the (L, a, b) color system before heat treatment and after heat treatment at 260° C. for 10 minutes using a spectrophotometer CM-600d (manufactured by Konica Minolta Sensing Co., Ltd.).

<Hardness>

Pencil cores that were ground to have a flat surface and have hardness from B to 9H were pressed against the test piece at an angle of about 45 degrees, and the hardness of the pencil core which did not cause peeling of the coating film was recorded.

The formulations of the photosensitive polyimide resin compositions of Examples 1 to 6 and Comparative Examples 1 to 4 as well as the test results of the polyimide films formed therefrom are shown in Table 1.

TABLE 1

| | | | | | | | | | Comparative | | | |
|---|---|---|---|---|---|---|---|---|---|---|---|---|
| | | | Example | | | | | | Example | | | |
| | | | 1 | 2 | 3 | 4 | 5 | 6 | 1 | 2 | 3 | 4 |
| Formulation | photosensitive | A1 | 20 | 20 | 20 | 20 | 20 | 20 | 20 | 20 | 20 | 10 |
| | polyimide | | | | | | | | | | | |
| | titanium | B1 | 40 | | | 30 | 50 | 20 | | | 20 | 75 |
| | dioxide | B2 | | 40 | | | | | | | | |
| | | B3 | | | 40 | | | 20 | | | | |
| | | B4 | | | | | | | 40 | | | |
| | | B5 | | | | | | | | 40 | | |
| | photo radical | C1 | 5 | 5 | 5 | 5 | 5 | 5 | 5 | 5 | 5 | 5 |
| | initiator | | | | | | | | | | | |
| | crosslinking | D1 | 5 | 5 | 5 | 5 | 5 | 5 | 5 | 5 | 5 | 5 |
| | agent | D2 | 10 | 10 | 10 | 10 | 10 | 10 | 10 | 10 | 10 | |
| | | D3 | 20 | 20 | 20 | 30 | 10 | 20 | 20 | 20 | 40 | 5 |

| Thickness(μm) | | 15 | 15 | 15 | 15 | 15 | 15 | 15 | 15 | 15 | 15 |
|---|---|---|---|---|---|---|---|---|---|---|---|
| Evaluation | Pattern Formability | A | A | A | A | A | A | A | B | A | B |
| results | Reflectance (R %) | 88.3 | 86.8 | 88.5 | 85.7 | 89.1 | 89.8 | 81.1 | 88.6 | 79.2 | 89.3 |
| | Yellowness (b value) | 0.9 | 1.9 | 0.7 | 1.8 | 0.1 | 0.2 | 2.7 | 0.1 | 2.1 | 0.1 |
| | Thermal yellowing | 1.8 | 1.9 | 1.6 | 1.9 | 1.5 | 1.5 | 2.5 | 1.6 | 2.8 | 1.5 |
| | resistance (ΔE) | | | | | | | | | | |
| | Hardness | 8H | 8H | 8H | 7H | 8H | 8H | 5H | 8H | 5H | 8H |

Note: The unit of the components in Table 1 is part by weight.

The polyimide films prepared in the examples and the comparative examples of the present invention are white due to the addition of titanium dioxide as a white pigment, and have shielding capacity. As shown in Table 1, the polyimide films formed from the photosensitive polyimide resin compositions of the present invention are excellent in yellowness, reflectance, hardness, and heat resistance.

In summary, after the pre-baking, exposure, development and post-baking, the protective film formed from the photosensitive polyimide resin composition of the present invention can have both high reflectance and low thermal yellowing. Further, the cured film can be applied to a substrate used in a substrate-like PCB, a liquid crystal display, an organic electroluminescence display, a semiconductor device, or a printed circuit board.

Those described above are only the preferred embodiments of the present invention, and are not intended to limit the scope of the present invention. All the simple and equivalent variations and modifications made according to the claims and the description of the present invention are still within the scope of the present invention.

1. A photosensitive polyimide resin composition, comprising (a) a photosensitive polyimide represented by formula (1); (b) titanium dioxide having a particle size of 0.2 μm to 10 μm; (c) a photo radical initiator; (d) a radical polymerizable compound; and (e) a solvent for dissolving the photosensitive polyimide; 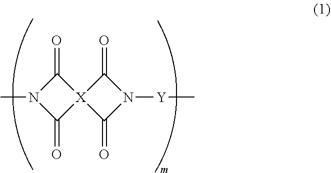
wherein X is derived from a tetracarboxylic dianhydride, Y is derived from a diamine, and m is a positive integer from 1 to 5000.

2. The resin composition according to claim 1, wherein the tetracarboxylic dianhydride is selected from the group consisting of 3,3′,4,4′-biphenyltetracarboxylic dianhydride; 3,3′,4,4′-benzophenone tetracarboxylic dianhydride; 4,4′-oxydiphthalic anhydride; bis(3,4-dicarboxyphenyl)methane dianhydride; 2,2-di(3,4-dicarboxyphenyl)propane dianhydride; 2,2-bis(3,4-dicarboxyphenyl)propane dianhydride; 1,3-bis(3,4-dicarboxyphenoxy)benzene dianhydride; 1,4-bis(3,4-dicarboxyphenoxy)benzene dianhydride; 4,4′-bis(3,4-dicarboxyphenoxy)biphenyl dianhydride; 2,2-bis[4-(3,4-dicarboxyphenoxy)phenyl]propane dianhydride; ethylene glycol bis(trimellitic anhydride) (TMEG); propylene glycol bis(trimellitic anhydride) (TMPG); 1,2-propanediol bis(trimellitic anhydride); butanediol bis(trimellitic anhydride); 2-methyl-1,3-propanediol bis(trimellitic anhydride); dipropylene glycol bis(trimellitic anhydride); 2-methyl-2,4-pentanediol bis(trimellitic anhydride); diethylene glycol bis(trimellitic anhydride); tetraethylene glycol bis(trimellitic anhydride); hexaethylene glycol bis(trimellitic anhydride); neopentyl glycol bis(trimellitic anhydride); hydroquinone bis(2-hydroxyethyl)ether bis(trimellitic anhydride); 2-phenyl-5-(2,4-xylyl)-1,4-hydroquinone bis(trimellitic anhydride); 2, 3-dicyanohydroquinone cyclobutane-1,2,3,4-tetracarboxylic dianhydride; 1,2,3,4-cyclopentanetetracarboxylic dianhydride; 1,2,4,5-cyclohexane tetracarboxylic dianhydride; bicyclo[2.2.1]heptane-2,3,5,6-tetracarboxylic dianhydride; bicyclo[2.2.2]oct-7-ene-2,3,5,6-tetracarboxylic dianhydride; bicyclo[2.2.2]octane-2,3,5,6-tetracarboxylic dianhydride; 2,3,5-tricarboxy-cyclopentyl acetic dianhydride; bicyclo[2.2.1]heptane-2,3,5-tricarboxy-6-acetic dianhydride; decahydro-1,4,5,8-dimethanolnaphthalene-2,3,6,7-tetracarboxylic dianhydride; butane-1,2,3,4-tetracarboxylic dianhydride; 3,3′,4,4′-dicyclohexyltetracarboxylic dianhydride; and combinations thereof.

3. The resin composition according to claim 1, wherein the diamine is selected from the group consisting of 3,3′-diaminodiphenyl sulfone; 4,4′-diaminodiphenyl sulfone; 3,3′-methylenediphenylamine; 4,4′-methylenediphenylamine; 2,2-bis(4-aminophenyl)propane; 2,2-bis(4-aminophenyl)hexafluoropropane; 2,2′-bis(trifluoromethyl)benzidine; 2,2′-dimethylbenzidine; 3,3′-dihydroxybenzidine; 1,3-bis(3-aminophenoxy)benzene; 1,3-bis(4-aminophenoxy)benzene; 1,4-bis(4-aminophenoxy)benzene; 4,4′-bis(4-aminophenoxy)biphenyl; 2,2-bis[4-(4-aminophenoxy)phenyl]propane; 2,2-bis[4-(4-aminophenoxy)phenyl]-1,1,1,3,3,3-hexafluoropropane; 1,3-bis[4-(3-aminophenoxy)benzoyl]benzene; 4,4′-diaminobenzanilide; 2,2-bis(3-amino-4-hydroxyphenyl)hexafluoropropane; 5-amino-2-(p-aminophenyl)benzoxazole; 6-amino-2-(p-aminophenyl)benzoxazole; and combinations thereof.

4. The resin composition according to claim 1, wherein the titanium dioxide has a particle diameter of 0.3 μm to 5 μm.

5. The resin composition according to claim 1, wherein the titanium oxide accounts for 30% to 70% by weight of a solid content of the photosensitive polyimide resin composition.

6. The resin composition according to claim 5, wherein the titanium oxide accounts for 35% to 50% by weight of a solid content of the photosensitive polyimide resin composition.

7. The resin composition according to claim 1, wherein the radical polymerizable compound is a compound having at least two (meth)acrylate groups.

8. The resin composition according to claim 1, wherein the radical polymerizable compound is a polyamic acid ester having the (meth)acrylate group.

9. The resin composition according to claim 8, wherein a content of the polyamic acid ester having the (meth)acrylate group in the radical polymerizable compound is from 10% to 98% by weight.

10. The resin composition according to claim 1, wherein a polyimide film formed therefrom has a reflectance of 85% or more at a wavelength of 450 nm.

11. The resin composition according to claim 1, wherein a color difference ΔE*ab of a polyimide film formed therefrom before and after 260° C. reflow is 2 or less.

12. The resin composition according to claim 1, wherein a color difference ΔE*ab of a polyimide film formed therefrom before and after 200° C. baking for 2 hours is 2 or less.

13. The resin composition according to claim 1, wherein a hardness of a polyimide film formed therefrom is 7H or more.

14. The resin composition according to claim 1, wherein a polyimide film formed therefrom has a pore pattern having a pore diameter of 100 μm or less.

15. A polyimide film formed from the resin composition according to claim 1.

16. The polyimide film according to claim 15, wherein a color difference ΔE*ab thereof before and after 260° C. reflow is 2 or less.

17. The polyimide film according to claim 15, wherein a color difference ΔE*ab thereof before and after 200° C. baking for 2 hours is 2 or less.

18. The polyimide film according to claim 15, wherein a hardness thereof is 7H or more.

19. The polyimide film according to claim 15, wherein a pore pattern thereof has a pore diameter of 100 μm or less.

20. A substrate, comprising the polyimide film according to claim 15.
